(19) United States
(12) Patent Application Publication
(10) Pub. No.: US 2025/0068081 A1
(43) Pub. Date: Feb. 27, 2025

(54) ILLUMINATION SYSTEM, PROJECTION ILLUMINATION FACILITY AND PROJECTION ILLUMINATION METHOD

(71) Applicant: Carl Zeiss SMT GmbH, Oberkochen (DE)

(72) Inventors: Stig Bieling, Aalen (DE); Markus Schwab, Aalen (DE); Susanne Beder, Aalen (DE)

(21) Appl. No.: 18/945,626

(22) Filed: Nov. 13, 2024

Related U.S. Application Data
(63) Continuation of application No. PCT/EP2023/062880, filed on May 15, 2023.

(30) Foreign Application Priority Data
May 25, 2022 (DE) 102022205273.0

(51) Int. Cl. G03F 7/00

(52) U.S. Cl. CPC G03F 7/70075; G03F 7/702; G03F 7/70208; G03F 7/70225; G03F 7/70275

(57) ABSTRACT

An illumination system for a microlithography projection illumination facility for illuminating a sample arranged in a region of an object plane of a downstream projection lens with illumination light generated from light from a primary light source is a double-field illumination system for receiving a single light beam coming from the primary light source and generating therefrom two illumination beams. A first illumination beam is guided along a first illumination beam path to a first illumination field outside the optical axis of the projection lens in the exit plane of the illumination system. At the same time, a second illumination beam is guided along a second illumination beam path to a second illumination field opposite the first illumination field relative to the optical axis and outside the optical axis in the exit plane.

### CROSS-REFERENCE TO RELATED APPLICATIONS

The present application is a continuation of, and claims benefit under 35 USC 120 to, international application No. PCT/EP2023/062880, filed May 15, 2023, which claims benefit under 35 USC 119 of German Application No. 10 2022 205 273.0, filed on May 25, 2022. The entire disclosure of each of these applications is incorporated by reference herein.

### FIELD

The disclosure relates to an illumination system for illuminating a pattern arranged in an object plane of a projection lens, a projection exposure apparatus having such an illumination system, and a projection exposure method which can be carried out with the aid of the illumination system.

### BACKGROUND

These days, microlithographic projection exposure methods are predominantly used for producing semiconductor devices and other finely structured components. Masks (reticles) that carry or create the pattern of a structure to be imaged, e.g. a line pattern of a layer of a semiconductor device, are used in this case. The pattern is arranged in a projection exposure apparatus between an illumination system and a projection lens in the region of the object plane of the projection lens and illuminated in the region of the effective object field with illumination radiation provided by the illumination system. The effective object field is the part of the object field which is usable for an image that is actually used for the image. The radiation changed by the pattern travels as a projection beam through the projection lens, which images the pattern in the region of the effective image field which is optically conjugate to the effective object field onto the substrate to be exposed. The substrate usually carries a layer (photoresist) sensitive to the projection radiation.

When selecting suitable projection exposure apparatuses and methods for a lithography process, different technical and economic criteria are typically taken into account, which are based, among other things, on the typical structure sizes of the structures to be produced within the exposed substrate.

Projection exposure apparatuses with high-NA projection lenses, which typically operate at operating wavelengths in the range of deep ultraviolet radiation (DUV), e.g. at approx. 193 nm, are used for producing relatively fine, critical structures.

By contrast, for the production of medium-critical or non-critical layers with typical structure sizes of significantly more than 150 nm, projection exposure apparatuses that are designed for operating wavelengths of more than 200 nm are traditionally used. In this wavelength range, purely refractive (dioptric) reduction lenses are often used.

Projection exposure apparatuses for an operating wavelength of 365.5 nm±2 nm (so-called i-line systems) have been in use for a long time. They use the i-line of mercury vapor lamps, wherein the natural bandwidth thereof is limited to a narrower used bandwidth Δλ, e.g. of about 2 nm, via a filter or in other ways. In such light sources, ultraviolet light of a relatively wide wavelength band is used in the projection.

Most conventional projection exposure apparatuses are designed to image a single effective object field into a single effective image field. There are also approaches to use two beam paths at the same time, e.g. to increase throughput.

U.S. Pat. No. 8,634,060 describes a projection exposure apparatus that can expose two masks and two wafers simultaneously. The light from a single light source is alternately transmitted via a fast optical switch through two separate, identical projection systems, each comprising an illumination system and a projection lens.

US 2008/259440 describes a projection exposure apparatus that works with two separate masks and two separate illumination systems, wherein the projection beam paths in the projection lens are merged via a triangular prism.

US 2010/0053738 (corresponding to U.S. Pat. No. 8,705,170) describes projection lenses that use a single mask and branch the projection beam path in the projection lens with the aid of deflection mirrors in such a way that two separate image-side lens parts are formed, which generate two image fields, so that two wafers can be exposed simultaneously. US 2010/0053583 discloses illumination systems, which can simultaneously illuminate two separate illumination fields located at a distance from each other on the same mask. Diffractive optical elements or prisms are provided for splitting the beam coming from the light source. Lens arrays of a fly's eye lens are provided for the homogenization of the illumination radiation.

Projection exposure apparatuses with two projection beam paths are, for example, described in U.S. Pat. No. 8,384,875 using schematic examples. For illuminating the mask, two illumination systems are provided, which can be constructed separately from each other or integrated into a common illumination system (FIG. 12). There are also schematic examples of catadioptric projection lenses. Specification data for reworking the systems are not disclosed.

### SUMMARY

The disclosure seeks to provide practically feasible concepts for dual-field illumination systems, a projection exposure apparatus equipped therewith, and projection exposure methods which can be carried out therewith.

According to an aspect of the disclosure, an illumination system for a microlithography projection exposure apparatus is provided. The illumination system is configured to illuminate a pattern arranged in the region of an object plane of a downstream projection lens with illumination light, which is generated from light from a primary light source. The illumination system is designed as a dual-field illumination system for receiving a single light beam originating from the primary light source and for producing two illumination beams therefrom. In operation, a first illumination beam is guided along a first illumination beam path to a first illumination field, which is arranged outside the optical axis of the projection lens in the exit plane of the illumination system. At the same time, a second illumination beam is guided along a second illumination beam path to a second illumination field, which lies opposite the first illumination field with reference to the optical axis and is arranged outside the optical axis in the exit plane. The exit plane of the illumination system corresponds to the object plane of the projection lens.

The illumination system comprises a refractive pupil-shaping unit for receiving light from the primary light source and for generating a two-dimensional intensity distribution in a pupil-shaping surface of the illumination system. The two-dimensional intensity distribution in the pupil-shaping surface substantially determines the angular distribution of the rays guided to the exit plane. Furthermore, a refractive field-shaping system optically downstream of the pupil-shaping unit is provided, which comprises a homogenization unit for homogenizing the light received from the pupil-shaping unit and for dividing the illumination light into the first and second illumination beams.

The pupil-shaping unit shapes the two-dimensional intensity distribution exclusively with the aid of refractive optical elements, i.e. by refraction of the light to be conditioned on correspondingly designed smooth surfaces of optical elements. The use of one or more diffractive optical elements is dispensed with. Although diffractive optical elements in general offer the possibility of producing one or more output beams with very individually adjustable properties from an input beam, beam shaping via diffraction is usually associated with light losses and stray light is produced, which can negatively affect the function. If, on the other hand, the pupil-shaping unit is constructed exclusively with refractive optical elements, the pupil illumination can be generated with low optical losses.

In order to help ensure that the illumination fields are illuminated as homogeneously as reasonably possible with light from the light source and at the same time the light loss between the pupil-shaping surface and the exit surface remains low, the refractive field-shaping system comprising the homogenization unit for homogenizing the light received from the pupil-shaping unit and for dividing the illumination light into the first and the second illumination beam is provided.

This assembly therefore has a dual function, to be precise the task of homogenizing the illumination radiation and the division into two illumination beams. The division is due to the special design of the optical components of the homogenization unit. Through the integration of several functions (homogenization and division) by way of optical components of the homogenization unit, it is also possible to contribute to the use of the light from the primary light source to illuminate, with as little loss of intensity as reasonably possible, the pattern and thus contribute to increasing the throughput.

There are different ways to implement this.

In some embodiments, the homogenization unit has a first grid arrangement having first refractive grid elements for receiving light of the two-dimensional intensity distribution and for generating a grid arrangement of secondary light sources, and a downstream second grid arrangement having second refractive grid elements for receiving light from the secondary light sources and at least partially superposing light from the secondary light sources in the exit plane. The first grid elements are used to divide the beam into a multiplicity of optical channels. Each of the first grid elements generates an optical channel belonging to the secondary light source. The shape or aperture of the first grid elements usually determines the shape of the illumination fields. For example, the first grid elements can be rectangular.

Each of the second grid elements is assigned to two adjacent first grid elements and formed by a lens element which has a first portion lying in a first optical channel and a second portion lying in a second optical channel, wherein the portions have different surface shapes and, because of this, different optical effects.

The arrangement can be such that first grid elements which are adjacent in one direction are assigned alternately to the first illumination field and the second illumination field. This can contribute to an even distribution of the intensity distribution originating from the pupil-shaping surface over the illumination fields. Since each illumination field practically receives intensity from closely neighboring locations in the pupil-shaping surface, the two illumination fields can have substantially the same angular distributions, with the result that the illumination conditions of the pattern in both illumination fields are also substantially the same.

In order to achieve a substantially uniform distribution of the intensity over both illumination fields, at least one surface of the lens element in the second grid elements can be aspherically curved. Another surface may be spherically curved, which can simplify manufacturing. However, the entry surface and the exit surface can be aspherically curved such that the second grid elements resemble double aspheric lenses in this respect.

In order to achieve a relatively sharp division of the radiation incident on a lens element into the two illumination fields to be illuminated, provision can be made for a buckling line to run between the first portion and the second portion of a lens element on at least one surface of the lens element, that is, a line that forms a transition between the adjacent portions which is not continuously differentiable.

The first grid arrangement and the second grid arrangement can be regarded as an integral part of a specially designed fly's eye lens, wherein the second grid arrangement is substantially formed of off-axis lens element portions, of which at least one side is aspheric and the size of each corresponds to the size of an assigned first grid element. In the second grid arrangement, a dense arrangement of refractive powers with transitions that are not continuously differentiable is obtained. For example, a dense arrangement of refractive powers alternating in a spatial direction with two different surface shapes may be provided.

In some embodiments, the homogenization unit comprises an integrator rod arrangement comprising an entry integrator rod having an entry surface and an exit surface, and a first exit integrator rod optically coupled to a first partial surface of the exit surface and a second exit integrator rod optically coupled to a second partial surface of the exit surface, wherein an exit surface of the first exit integrator rod is assigned to the first illumination field and an exit surface of the second exit integrator rod is assigned to the second illumination field.

Such homogenization units use a different light mixing principle. An integrator rod is substantially a long rod made of a material which is transparent to the illumination light. The cross section of the rod is usually polygonal, such as rectangular. The rod has an entry surface optically facing the light source and an opposite exit surface. Light which enters the entry surface at suitable angles is optionally reflected several times by total internal reflection at the side surfaces of the integrator rod and then exits in substantially homogenized form through the exit surface. By setting the angular distribution at the entry, the number of total internal reflections of a ray at the side surfaces and thus the homogenization effect can be influenced.

In the integrator rod arrangement, the division into the two illumination beam paths takes place at the exit surface of the entry integrator rod. There is a virtual separation point between the first and the second partial surface in order to divide the emerging light over two disjoint exit integrator rods operated in parallel. The exit integrator rods can be directly coupled to the exit surface of the entry integrator rod without the desire for further intermediate optical elements. It is also possible that one or more optical elements for deflecting the passing radiation are provided between the entry integrator rod and the exit integrator rods.

In some embodiments, the entry integrator rod and the exit integrator rods each have a constant cross-sectional shape and cross-sectional size in the axial direction, and arranged between the exit surface of the entry integrator rod and each of the entry surfaces of the exit integrator rods is a prism arrangement for beam redirection from a location close to the axis with respect to a central axis of the entry integrator rod to a location of the exit integrator rods located away from the axis at a distance from the central axis of the entry integrator rod. With reference to the central axis, the entry surface of the entry integrator rod is then centered with respect to the central axis, while the exit surfaces of the exit integrator rods are located at a distance from this central axis on opposite sides of the central axis.

There are also embodiments without intermediate prism arrangements. According to one exemplary embodiment, the first exit integrator rod and the second exit integrator rod are formed as a “tapered integrator,” wherein a cross-sectional size decreases continuously from the entry side to the exit side. Here, too, the entry surfaces can be directly coupled to the first and second partial surfaces of the exit surface of the entry integrator rod. If desired, a prism arrangement may be provided, e.g. for beam deflection.

Further features and aspects of the disclosure are evident from the claims and from the description of exemplary embodiments of the disclosure, which will be explained below with reference to the figures.

### BRIEF DESCRIPTION OF THE DRAWINGS

FIG. 1 shows a schematic illustration of a projection exposure apparatus according to one exemplary embodiment.

FIG. 2 shows a schematic top view of the object plane of the projection lens with two effective off-axis object fields.

FIG. 3 shows a schematic overview of an exemplary embodiment for a dual-field illumination system having an integrator rod arrangement.

FIG. 4 shows the integrator rod arrangement from FIG. 3 in more detail.

FIGS. 5A to 5D show variants of integrator rod arrangements of exemplary embodiments.

FIG. 6 shows an integrator rod arrangement with two tapered exit integrator rods.

FIG. 7 shows a schematic overview of an exemplary embodiment for a dual-field illumination system with grid elements in a homogenization unit.

FIG. 8 shows the homogenization unit of FIG. 7 in more detail.

FIG. 9 shows a schematic meridional lens element sectional view of a projection lens according to an exemplary embodiment.

FIG. 10 shows an enlarged section of the region of the deflection units in the projection lens of FIG. 9.

FIGS. 11A to 11C show three folding situations in comparison.

FIGS. 12A to 12B show a variant of single-field scanning.

FIGS. 13A to 13B show a variant of double-field scanning.

FIG. 14 shows a schematic meridional lens element sectional view of a catadioptric projection lens with two intermediate images, a concave mirror, a two-stage reflective deflection unit, and a single-stage deflection unit.

### DETAILED DESCRIPTION OF THE EXEMPLARY EMBODIMENTS

In the following description of embodiments, the term “optical axis” denotes a straight line or a sequence of straight line portions through the centers of curvature of the optical elements. The optical axis is folded at folding mirrors (deflection mirrors) or other reflective surfaces. In the examples, the object is a mask (reticle) with the pattern of an integrated circuit; it may also relate to a different pattern, for example of a grating. In the examples, the image is projected onto a wafer provided with a photoresist layer, the wafer acting as a substrate. Other substrates are also possible, for example elements for liquid crystal displays or substrates for optical gratings.

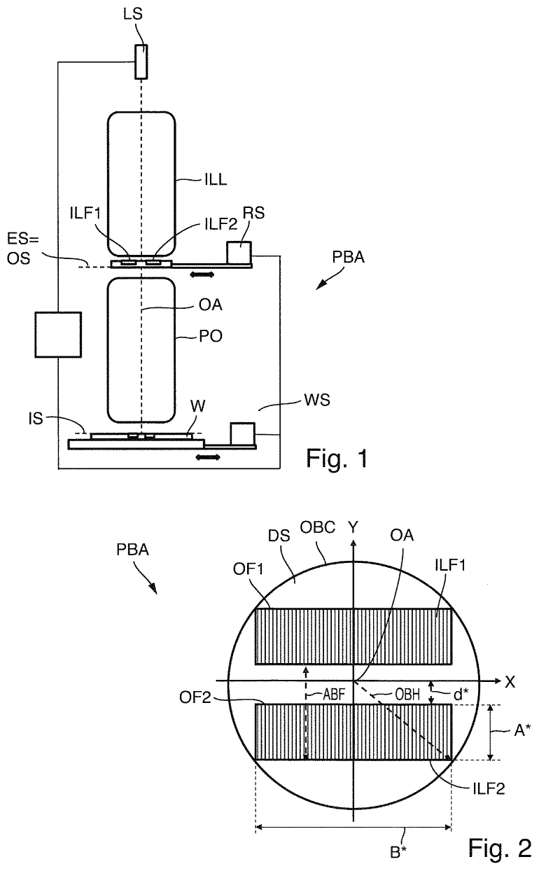

FIG. 1 shows an example of a microlithographic projection exposure apparatus PBA, which is utilizable in the production of semiconductor devices and other finely structured components and which operates with light or electromagnetic radiation from the ultraviolet (UV) range in order to obtain resolutions down to fractions of micrometers. A mercury vapor lamp serves as the primary radiation source or light source LS. The lamp emits a broad spectrum with emission lines of relatively high intensity I in wavelength ranges with centroid wavelengths at approx. 436 nm (visible light, blue, g-line), approx. 405 nm (visible light, violet, h-line), and approx. 365.5 nm (near ultraviolet, UV-A, i-line).

The projection exposure apparatus is an i-line system which uses only the light from the i-line, that is to say UV light around a central operating wavelength of approx. 365.5 nm. The natural full bandwidth of the i-line is restricted to a narrower used bandwidth Δλ, e.g. of about 2 nm, with the aid of a filter or in another way.

In its exit surface ES, an illumination system ILL connected downstream of the light source LS generates from the light from this single primary light source in each case two large, sharply delimited and substantially homogeneously illuminated illumination fields ILF1, ILF2 with beam angles which are adapted to the desired properties of telecentricity of the projection lens PO arranged downstream thereof in the light path.

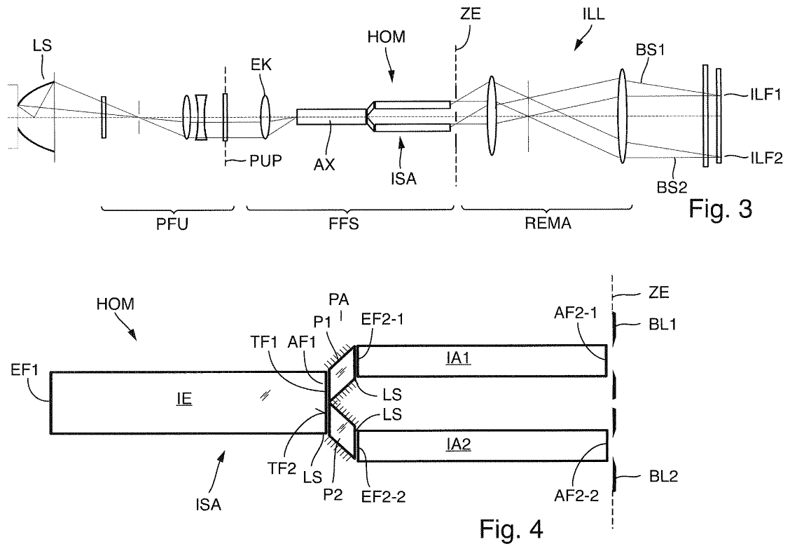

The optical components that receive the light from the light source LS and form from the light illumination radiation which is directed at the reticle M are part of the illumination system ILL of the projection exposure apparatus. The illumination system is a dual-field illumination system. Exemplary embodiments will be explained below in connection with FIGS. 3 to 8.

The illumination system ILL has devices for setting different illumination modes (illumination settings) and can, for example, be switched between conventional on-axis illumination with a different degree of coherence o and off-axis illumination.

Arranged downstream of the illumination system is a device RS for holding and manipulating the mask M (reticle) in such a way that the pattern arranged at the reticle lies in the object plane OS of the projection lens PO, which coincides with the exit plane ES of the illumination system and which is also referred to here as reticle plane OS.

The substrate to be exposed, which is a semiconductor wafer W in the exemplary case, is held by a device WS, which comprises a scanner drive in order to move the wafer synchronously with the reticle M perpendicular to the optical axis OA in a scan direction (y-direction). The device WS, which is also referred to as “wafer stage,” and the device RS, which is also referred to as “reticle stage,” are integral parts of a scanner device which is controlled by a scan control device, which in the embodiment is integrated in the central control device CU of the projection exposure apparatus PBA.

FIG. 2 shows a schematic top view of the object plane OS of the projection lens PO (corresponding to the exit plane ES of the illumination system). As shown in this example, the illumination system ILL illuminates two off-axis illumination fields ILF1, ILF2 with the light from the light source in the exit plane (reticle plane, object plane of the projection lens). These illumination fields are each rectangular, can be sharply or softly delimited, and are substantially homogeneously illuminated. Each of the illumination fields defines an effective object field which is actually used in the projection exposure, so that a first effective object field OF1 and a second effective object field OF2 are located in the reticle plane. The two nominally identically dimensioned rectangular effective object fields lie in the y-direction on opposite sides of the optical axis OA, each with a distance outside the optical axis and have a height A*, measured parallel to the y-direction, and a width B*>A*, measured perpendicular thereto (in the x-direction or cross-scan direction). For example, the aspect ratio AR=B*/A* can be, for example, 2, 2.5, 3, 5, 10 or 15.

In the example case, the effective rectangular fields (i.e. those actually used for imaging) each have a width B*=104 mm and a height A*=56 mm. A distance ABF between corresponding field peripheries in the y-direction (field distance) is twice the distance d* of a field from the optical axis, i.e. 2×38 mm, plus a field height (56 mm), i.e. 132 mm. The circle OBC results from the rectangle with the sides B* (=104 mm) in the x-direction and 2*(A*+d*) (=188 mm) in the y-direction (scan direction).

In the rotationally symmetric system, the circle OBC, which is centered with respect to the optical axis OA, encloses the effective object fields OF1, OF2 and touches their corners, determines the size of the object field circle within which the optical correction corresponds to the specification at all field points. This also applies to all the field points in the effective object fields. The larger this object field is, the more complicated the correction of aberrations becomes. In this case, the size of the circle is parameterized by the object field radius OBH or half the object field diameter OBH, which simultaneously corresponds to the maximum field height of an object field point. The object field height OBH is approx. 107 mm.

The effective image fields IF1, IF2 in the image surface IS, which are optically conjugate to the effective object fields OF1, OF2, have the same shape and the same aspect ratio between height A and width B as the associated effective object fields, but the absolute field size is reduced for reducing projection lenses (with (| [symbol] |<1) by the imaging scale [symbol] of the projection lens, i.e. A=| [symbol] |A* and B=| [symbol] |B*.

A distance ABF (field distance) measured in the scan direction (y-direction) between the edges of the effective object fields lying in each case on the same side in the y-direction is selected so that the corresponding distance between the corresponding longer edges of the effective image fields IF1, IF2 is exactly the length of a “die” to be exposed. This length is 33 mm in the current standard. In semiconductor and microsystem technology, the term “die” refers to a single non-enclosed piece of a semiconductor wafer, as a single semiconductor chip without a housing or package.

FIG. 3 shows a schematic overview of a first exemplary embodiment for an illumination system ILL. The primary light source LS is a mercury vapor lamp with a collector mirror, which reflects the light collected into an entry opening of the illumination system. An alternative (not illustrated) uses a laser as the light source, e.g. a frequency-tripled solid-state laser with a wavelength of approx. 355 nm.

The primary light source is followed by a pupil-shaping unit PFU, which is constructed exclusively with refractive optical components and is designed to generate a defined, local (two-dimensional) intensity distribution in a following pupil surface PUP of the illumination system ILL, and which is sometimes also referred to as a secondary light source or as an illumination pupil. Since desired properties of the illumination radiation are influenced or shaped by this local intensity distribution, this pupil surface is also referred to as pupil-shaping surface PUP.

The pupil-shaping unit PFU can be adjustable such that different local illumination intensity distributions in the circular illumination pupil can be set depending on the control of optical components of the pupil-shaping unit, for example a conventional illumination setting with a circular illumination spot centered around the optical axis AX, dipole illumination or quadrupole illumination.

A refractive field-shaping system FFS is optically connected downstream of the pupil-shaping unit PFU. It contains the optical components that shape the illumination intensity distribution in the exit surface ES of the illumination system from the light from the pupil-shaping surface. The field-shaping system FSF comprises a homogenization unit HOM for the homogenization of the light received from the pupil-shaping unit. The homogenizing unit has a dual function, since the optical components are also designed in a such a way that the illumination light is divided into a first illumination beam BS1 and a second illumination beam BS2, which are incident on the exit plane at mutual distance from each other. The field-shaping system FFS comprises an input-coupling optical unit EK, which collects the light coming from the pupil-shaping surface and couples it into an entry surface EF1 of an integrator rod arrangement ISA. This is shown enlarged in FIG. 4.

The integrator rod arrangement ISA comprises an entry integrator rod IE, which has a planar entry surface EF1, a planar exit surface EF2 parallel thereto, and four planar side surfaces, which form a rectangular cross section. The entry integrator rod is formed of a material which is transparent to the illumination light. The light is mixed within the entry integrator rod by multiple total internal reflections at the uncoated or optionally coated outer surfaces (side surfaces) of the integrator rod and thus homogenized and exits in at least partially homogenized form at the exit surface AF1. The entry integrator rod has a continuously rectangular cross section and defines a longitudinal central axis that lies on the optical axis AX of the illumination system.

The integrator rod arrangement further comprises a first exit integrator rod IA1 and a second exit integrator rod IA2, each having an entry surface EF2-1 and EF2-2, respectively, and an exit surface AF2-1 and AF2-2, respectively. The two exit integrator rods IA1 and IA2 each have a rectangular cross-sectional shape and a cross-sectional area which is substantially half as large as the cross-sectional area of the entry integrator rod IE.

The exit integrator rods IA1, IA2 are arranged on diametrically opposite sides at a distance from the optical axis AX of the illumination system. The first exit integrator rod IA1 is optically coupled to a first partial surface TF1 of the exit surface of the entry integrator rod in such a way that light, which exits through the first partial surface TF1, exclusively enters the first exit integrator rod IA1. The same applies to the opposite side, where the light from the partial surface TF2 enters the second exit integrator rod IA2.

Between the entry integrator rod IE and the two exit integrator rods IA1, IA2, two prisms P1 and P2 of a prism arrangement PA are arranged. The first prism P1 has a rectangular, planar entry surface, which directly follows the first partial surface TF1 with an intermediate air gap LS and receives the radiation emerging from this partial surface. The planar exit surface has the same size and lies, with an intermediate air gap, directly in front of the entry surface of the first exit integrator rod IA1. The prism furthermore has two planar side surfaces, which are oriented at an angle of 45° to the entry and exit surfaces and each have a reflective coating. They can be made reflective, for example, by applying an aluminum layer or a dielectric coating.

The two deflections at mirror surfaces of a prism that have a parallel offset deflect the light emerging from a partial surface TF to a position further away from the optical axis. Each of the prisms thus optically connects one of the exit integrator rods IA1, IA2 to an assigned partial surface TF1, TF1 of the exit surface AF1 of the entry integrator rod and guides the light from a position close to the axis to a location far away from the axis.

Using this arrangement, the light entering the entry integrator rod IE is evenly divided substantially in equal parts over the exit surface AF2-1 of the first exit integrator rod and the exit surface AF2-2 of the second exit integrator rod and at the same time mixed both in the entry integrator rod and in the exit integrator rods by multiple total internal reflections.

Immediately at the exit of the first exit integrator rod IA1 lies an intermediate field plane ZE of the illumination system. An adjustable field stop BL1 is arranged there, which allows the actual usable field size of the first illumination field IF1 to be infinitely adjusted. A corresponding second field stop BL2 is arranged at the exit of the second exit integrator rod.

A following lens REMA, also known as a REMA lens, images the intermediate field plane of the reticle mask system onto the exit plane of the illumination system or the object plane of the following projection lens. There, the first illumination beam generates the first illumination field ILF1 on one side of the optical axis AX, while the second illumination field ILF2 is illuminated on the opposite side at a distance from the optical axis with the aid of the second illumination beam SB2.

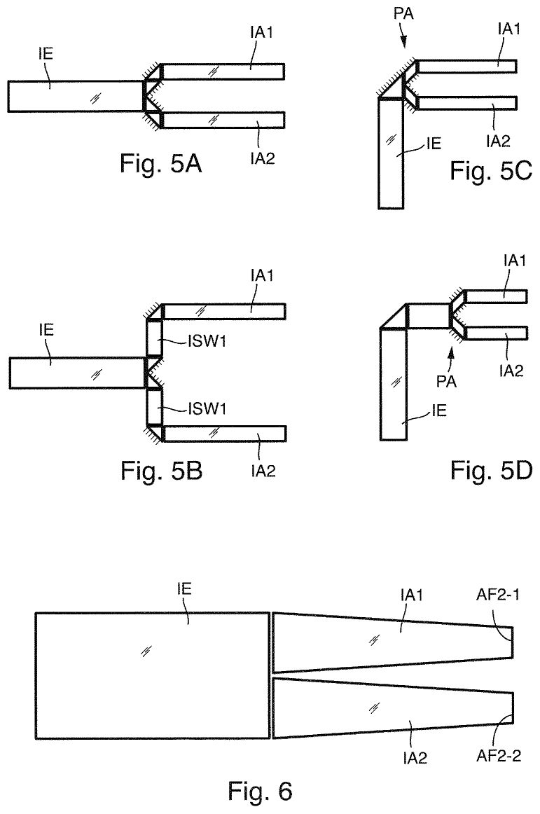

FIGS. 5A to 5C show a few variants of this basic concept. The variant of FIG. 5A differs from the example of FIG. 4 in that the prisms P1 and P2 there are replaced by a pair of triangular prisms. The hypotenuse surfaces of the triangular prisms are reflective in each case, the entry and exit surfaces are planar and adjoin an upstream or downstream element via an air gap.

FIG. 5B illustrates that a further integrator rod ISW1, ISW2 can be integrated between the entry integrator rod IE and the two exit integrator rods IA1, IA2 in each case.

FIG. 5C and FIG. 5D illustrate that the prism arrangement PA, which leads to the division into two illumination beam paths, does not necessarily have to be directly coupled to the exit side of the entry integrator rod. Rather, further deflection elements and/or integrator rod elements can be interposed.

In the exemplary embodiment of FIG. 6, there are no intermediate prisms and/or other optical elements between the entry integrator rod IE and the two exit integrator rods IA1 and IA2. In this exemplary embodiment, both exit integrator rods are each designed as a so-called “tapered integrator.” In each of the exit integrator rods IA1, IA2, the size of the rectangular entry surface EF1, EF2 substantially corresponds to half the area of the exit surface AF1 of the entry integrator rod IE, with the result that the light emerging from the associated partial surface is fully coupled into the exit integrator rod. However, while in the previous examples the integrator rods each have a constant cross-sectional shape and cross-sectional size over their lengths, the cross-sectional area of the exit integrators continuously changes in the example of FIG. 6 between the entry surface and the exit surface such that the two exit surfaces AF2-1 and AF2-2 are arranged diametrically opposite to the optical axis at a distance from the latter. By increasing the angles during the passage through the tapered integrator rods, different illumination may possibly be used at the entrance of the entry integrator rod and the rod illumination is adapted such that no violation of the conservation of etendue occurs.

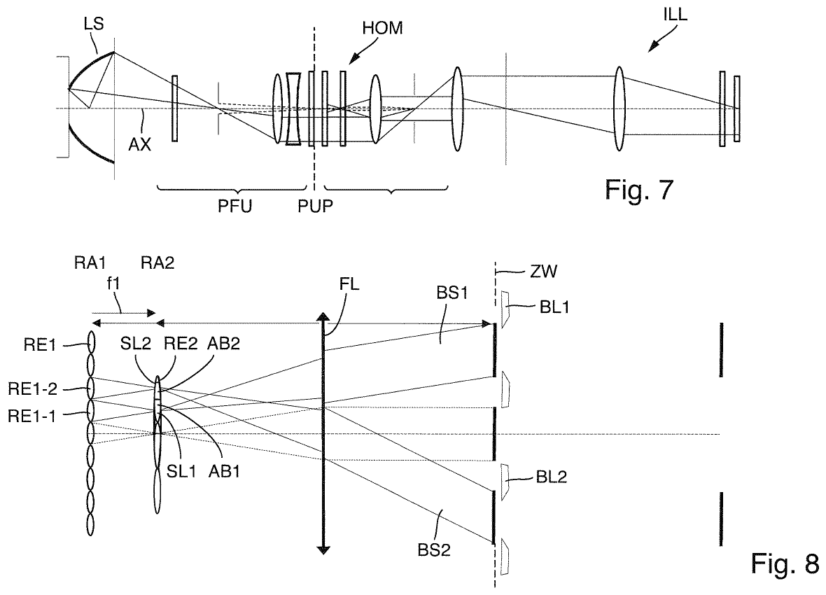

Based on FIG. 7, a different exemplary embodiment of an illumination system ILL will now be described. For reasons of clarity, functional groups having similar or corresponding functions as in the first exemplary embodiment, are designated accordingly. A significant difference from the previous exemplary embodiments lies in the construction and operation of the homogenization unit HOM, which is constructed substantially with the aid of a modified fly's eye lens. Details regarding the construction and function are shown in FIG. 8.

The homogenization unit HOM comprises a first grid arrangement RA1 with a multiplicity of first refractive grid elements RE1, which receive the light of the two-dimensional intensity distribution of the pupil-shaping surface PUP and generate therefrom a grid arrangement of secondary light sources SL1, SL2, etc., which are formed downstream thereof approximately at the distance of the focal length F1 of the first grid elements RE1. In this way, the illumination beam coming from the pupil-shaping surface is broken down into a multiplicity of optical channels, wherein each illuminated first grid element and the associated secondary light source are part of a separate optical channel.

There is a second grid arrangement RA2 with second refractive grid elements RA2, which is arranged optically downstream of the first grid arrangement, for example in the region of the secondary light sources SL1, etc., and serves to receive light from the respective optical channels or the secondary light sources and to contribute to the light coming from different optical channels being at least partially superposed in the region of the exit plane or image plane of the illumination system ILL. This superposition causes homogenization of the light intensity in the exit plane.

The cross-sectional area or aperture of the first grid elements RE1 determines the shape of the illuminated illumination fields and is rectangular in the example case. The first grid elements RE1 are also referred to as field honeycombs.

The second grid elements RE2 are also referred to as pupil honeycombs and are arranged close to the respective secondary light sources. They image the first grid elements RE1 via a downstream field lens element onto an intermediate field plane FE of the illumination system. The intermediate field plane is then imaged into the exit plane of the illumination system, as in the example above.

A special feature of this homogenization unit lies in the fact that each of the first grid elements RE1 generates (as in a conventional fly's eye lens) an optical channel belonging to the secondary light source.

However, each of the second grid elements RE2 is not only assigned to one first grid element, but to two, immediately adjacent first grid elements, e.g. the grid elements RE1-1 and RE1-2. The second grid elements are each formed by a lens element which is divided into two differently shaped portions. A first portion AB1 acts exclusively on the light of an assigned first grid element in its optical channel. A second portion AB2 is formed in a single piece with the first portion, is located exclusively in the adjacent second optical channel, and influences its light propagation accordingly.

In the example case, the first optical channel produced by a grid element R1-1 is influenced by the lower half of the following second grid element or its first portion AB1 such that the light is input into a first illumination beam BS1 via the field lens FL, while the light which is coupled into a second optical channel by the adjacent first grid element R1-2 is influenced by the second portion AB2 of the second grid element such that it is coupled into a second illumination beam BS2, which propagates with respect to the first illumination beam on the opposite side with respect to the optical axis AX.

In order to achieve the strongly differing optical effects at the second grid elements RE2, provision can be made for both the entry surface and the exit surface to be respectively aspheric in the first portion AB1 and in the second portion AB2. The surface shapes of the first portion and of the second portion do not merge smoothly into each other; rather, a buckling line forms as a separating line between the two portions on the surface of the second grid element.

A feature of this mixing concept is thus that a dense arrangement of several refractive powers, alternating in one spatial direction, with two different surface shapes is produced in the region of the pupil honeycombs (second grid elements RE2). For example, there is a dense arrangement of refractive powers with transitions that are not continuously differentiable. The second grid elements RE2 (pupil honeycombs) can be thought of as lens elements composed of off-axis lens element portions, of which at least one side is aspheric and the size of each can correspond to that of an associated field honeycomb.

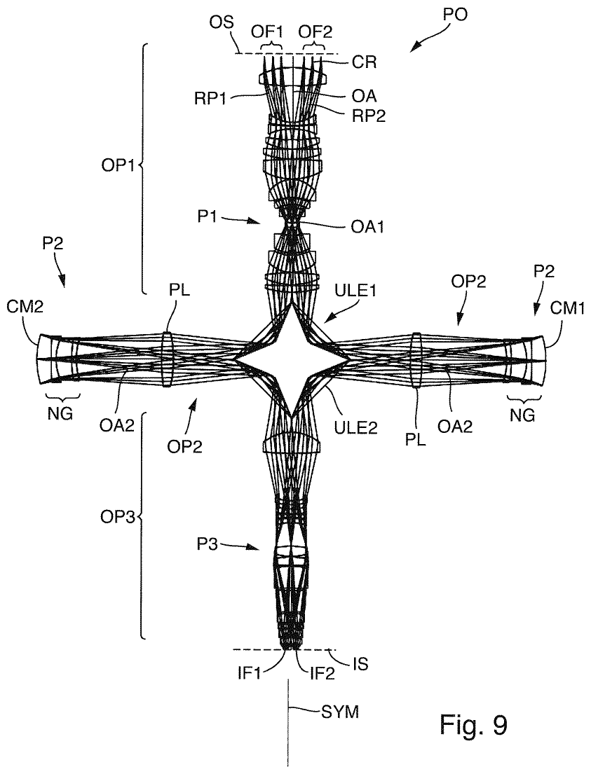

FIG. 9 shows a schematic meridional lens element sectional view of an embodiment of a catadioptric projection lens PO with selected beams for clarifying the imaging beam path of the projection radiation passing through the projection lens during operation. The projection lens is provided as an imaging system with a reducing effect for imaging a pattern of a mask arranged in its object plane OS at a reduced scale, for example the scale 1:4, onto its image plane IS, which is oriented parallel to the object plane.

The projection lens is designed according to one embodiment of the claimed disclosure and has an image-side numerical aperture NA in the range of 0.2<NA<0.4, e.g. NA=0.3.

The projection lens is designed as a double-field projection lens. It is able to image the first effective object field OF1 arranged outside the optical axis OA in the object plane OS along a first projection beam path RP1 into a first effective image field IF1 located outside the optical axis OA in the image plane IS, and simultaneously image a second effective object field OF2, arranged opposite to the first object field with respect to the optical axis outside the optical axis in the object plane, along a second projection beam path RP2 into a second effective image field IF2 located outside the optical axis in the image plane.

The projection lens comprises a multiplicity of optical elements, including numerous lens elements (e.g. between 15 and 25 lens elements) and also exactly two concave mirrors CM1, CM1, with exactly one concave mirror in each of the projection beam paths.

A majority of the lens elements (more than 50%, such as 60% or more, or 70% or more, or 80% or more) is arranged along first portions OA1 of the optical axis OA, wherein these first portions extend mutually perpendicular coaxially to the object plane OS and image plane IS. The concave mirrors CM1, CM2 are arranged on opposite sides of the first portions OA1 and define second portions OA2 of the optical axis, which together with the first portions define an axis plane (which lies in the drawing plane in FIG. 9). The concave mirrors of the example are arranged coaxially to each other on opposite sides of the first portions, the second portions OA2 of the optical axis are perpendicular to the first portions OA1, producing a cross shape.

The optical elements are arranged and formed mirror-symmetrically to a symmetry plane SYM, which extends perpendicular to the axis plane (here the drawing plane) through the first portions OA1. For each of the concave mirrors, there is in the assigned projection beam path a first deflection unit ULE1 for deflecting the radiation coming from the object plane OS to the concave mirror and a second deflection unit ULE2 for deflecting the radiation coming from the concave mirror in the direction of the image plane IS. The deflection units ULE1, ULE2 are each arranged on the side of the symmetry plane SYM facing the assigned concave mirror CM1 and CM2, respectively.

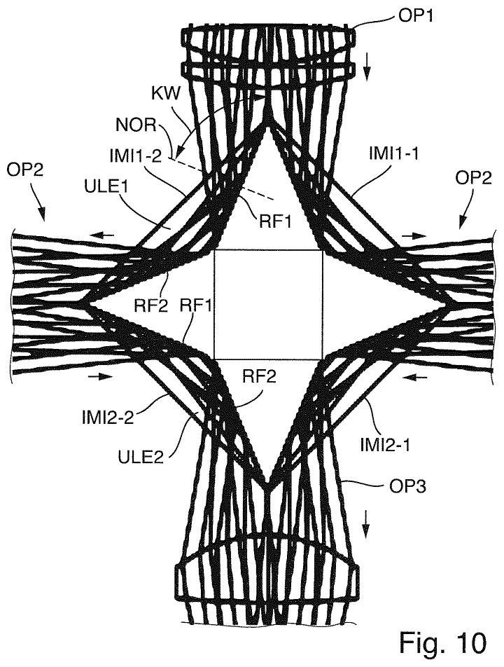

Between the object plane and the image plane, exactly two real intermediate images (generally referred to as IMI) of the assigned effective object field are generated in each of the projection beam paths RP1, RP2, to be precise IMI1-1, IMI2-1 in the first projection beam path and IMI1-2 and IMI2-2 in the second projection beam path (see FIG. 10).

A first lens part OP1, which is constructed exclusively with transparent optical elements and is thus refractive (dioptric) is designed in a manner such that the pattern in each of the illuminated effective object fields is imaged slightly reduced (imaging scale e.g. in the range of approx. 1.85:1 to approx. 1.75:1) into the first intermediate image IMI1-1, IMI1-2 of the respective projection beam path.

A second, catadioptric lens part OP2 images the first intermediate images of the projection beam paths onto the respective second intermediate image IMI2 substantially without changing the size. The second lens part OP2 comprises a separate concave mirror CM1, CM2 and three upstream double-passage lens elements for each of the projection beam paths. In the second lens part, the projection beam paths separate and run along separate optical paths through separate partial lenses before they are recombined to shared lens elements in the region of the second intermediate image IMI2. The second intermediate image IMI2 lies between the two individual mirrors of ULE2, i.e. the projection beam paths are still separated at the second mirrors of ULE2, and only then are they recombined.

A third, refractive lens part OP3 is designed to image the second intermediate images IMI2-1, IMI2-2 at a reduced scale into the image plane IS.

All lens elements of the first lens part OP1 and all lens elements of the third lens part OP3 and thus all lens elements on the first portions OA1 of the optical axis are common to both projection beam paths. The footprints of the projection beam paths on the individual lens element surfaces, i.e. the surface areas impinged by radiation, are symmetric to the symmetry plane SYM. Possible lens heating effects, especially in near-field lens elements, are therefore substantially symmetric to the symmetry plane, thus simplifying a possible correction.

Located in each of the projection beam paths between the object plane and the first intermediate image, between the first and second intermediate images, and between the second intermediate image and the image plane, are pupil surfaces or pupil planes P1, P2, P3 where the chief ray CR of the optical imaging intersects the optical axis OA. The stop of the system can be disposed in the region of the pupil surface P3 of the third lens part OP3. The pupil surface P2 within the catadioptric second lens part OP2 is located in the immediate vicinity of the respective concave mirror CM.

To support chromatic correction, a negative group NG with at least one diffusing negative lens is arranged in each of the two projection beam paths in the immediate vicinity of the associated concave mirror CM1, CM2 in a region close to the pupil. The “region close to the pupil” is a region in which the marginal ray height (MRH) of the imaging is greater than the chief ray height (CRH). The marginal ray height in the region of the negative group can be at least twice as great as the chief ray height.

To provide background: while the contributions of lens elements having a positive refractive power and lens elements having a negative refractive power in an optical system to the total refractive power, to the image field curvature and to the chromatic aberrations act in opposite directions, a concave mirror has a positive refractive power exactly like a positive lens element, but has an opposite effect on the image field curvature compared with a positive lens element. In addition, concave mirrors do not introduce chromatic aberrations. Catadioptric system parts with a concave mirror close to the pupil and an adjacent negative lens (Schupmann achromat) are therefore a well-suited mechanism for achromatizing projection lenses. Between the respective deflection unit and the negative group, a double-passage positive lens PL can be arranged, which can also be omitted in other exemplary embodiments (cf. table 3).

An exceptional technical feature relates to the design of the deflection units ULE1, ULE2. These are not designed as singly reflecting plane mirrors or deflection mirrors. Instead, the first deflection unit ULE1 and the second deflection unit ULE2 each have a substantially planar first reflection surface RF1 and directly following a substantially planar second reflection surface RF2. The reflection surfaces are tilted relative to the symmetry plane SYM by different tilt angles about tilt axes, which are orthogonal to the first and second portions. The first reflection surface RF1 is used to deflect the radiation coming from the object plane OS to the second reflection surface RF2, and the second reflection surface is used to deflect the radiation coming from the first reflection surface RF1 in the direction of the image plane.

In each projection beam path, the first reflection surface RF1 is that reflection surface which receives the beams coming from the last lens element of the first lens part OP1 and reflects them in the direction of the immediately following second reflection surface RF2. The latter then reflects the beams within the second lens part OP2 to the associated concave mirror CM. After reflection at the concave mirror and passing twice through the three upstream lens elements, the beams are then incident on the second deflection unit ULE2, whose first reflection surface RF1 deflects the beams to the second reflection surface RF2, which reflects in the direction of the first lens element of the third lens part OP3.

If the tilt angle KW of a reflection surface is defined as the angle that the surface normal NOR of the reflection surface encloses with the entry-side optical axis, the tilt angle of the first reflection surfaces on the side of the first lens part is 67.5° each. For the immediately following second reflection surfaces in each beam path, the tilt angle is then only 22.5°, i.e. corresponding to the supplementary angle of the first tilt angle, whose sum is 90°. For the second deflection units ULE2, i.e. those which deflect the beam coming from the respective concave mirrors CM in the direction of the third lens part OP3, the same applies, wherein now the second portions OA2 of the optical axis count as the entry-side optical axis.

With respect to the entry-side optical axis, a 90° deflection is thus achieved in two immediately successive steps, to be precise once by x degrees and the second time by 90−x°. The two associated reflection surfaces of a deflection unit are located on the same side of the symmetry plane SYM, to be precise on the side in which the associated concave mirror CM is located.

Both reflection surfaces RF1, RF2 of a deflection unit ULE are each located in the optical vicinity of the first intermediate image IMI1 of the associated projection beam path, with the result that the footprint of the beam on the reflection surface appears more or less rectangular with rounded corners and is located at a distance from the optical axis, but close thereto. More specifically, the first intermediate image lies between the two reflection surfaces RF1, RF2; in this way both reflection surfaces are close to the intermediate image. At an imaging scale of the first lens part OP1 with at most very small magnification or slight reduction, the size of the intermediate image is not or only slightly larger than the size of the generating effective object field OF, so that mirror surfaces with compact dimensions are sufficient to reflect the entire beam to the downstream optical element without vignetting. This applies for example to the reflection from the first reflection surface RF1 to the second reflection surface RF2, which can also be very compact in size because it still lies in the optical vicinity of the first intermediate image, such as in a region in which the subaperture ratio SAR is less than 0.3 in terms of absolute value. SAR can be between 0.2 and 0.3.

For explanatory purposes: the optical vicinity or the optical distance of an optical surface to a reference plane (e.g. a field plane or a pupil plane) is described in this application by the so-called subaperture ratio SAR. The subaperture ratio SAR of an optical surface is defined as follows for the purposes of this application:

$$SAR = sign ( CRH ) * ( MRH / ( \vert CRH \vert + \vert MRH \vert ) )$$

where MRH denotes the marginal ray height, CRH denotes the chief ray height, and the signum function sign (x) denotes the sign of x, where according to convention sign (0)=1. The chief ray height is the ray height of the chief ray of a field point of the object field with a maximum field height in terms of absolute value. The ray height should here be understood to be signed. Marginal ray height is the ray height of a ray with a maximum aperture starting from the intersection of the optical axis with the object plane. This field point does not need to contribute to the transfer of the pattern arranged in the object plane—especially in off-axis image fields.

The subaperture ratio is a signed variable that is a measure of the field vicinity or pupil vicinity of a plane in the beam path. By definition, the subaperture ratio is normalized to values between −1 and +1, wherein the subaperture ratio is zero in each field plane and wherein the subaperture ratio jumps from −1 to +1 or vice versa in a pupil plane. A subaperture ratio of 1 in terms of absolute value thus specifies a pupil plane.

Near-field planes thus have subaperture ratios which are close to 0, while near-pupil planes have subaperture ratios close to 1 in terms of absolute value. The subaperture ratio sign indicates the position of the plane in front of or behind a reference plane.

The reflection surfaces can be nominally designed as planar surfaces, i.e. define a mathematical plane aside from manufacturing tolerances. It is also possible to design individual or all reflection surfaces with defined deviations from a plane, with the result that the reflection surfaces can serve as correction surfaces for aberrations such as distortion, etc.

In the schematic example of FIG. 9, the reflection surfaces are each manufactured as individual mirrors and accommodated in separate mounts. The example of FIG. 10 shows that in each case two of the deflection mirrors or reflection surfaces can be designed combined as a triangular prism. These triangular prisms can be mounted together in the middle of the star-shaped cross section of the deflection unit. Alternatively, all mirrors used for the deflection can be combined and designed as a complex prism with a star-shaped side surface. The prism can, for example, be formed of a plurality of individual prisms, which are cemented or contact-bonded to one another.

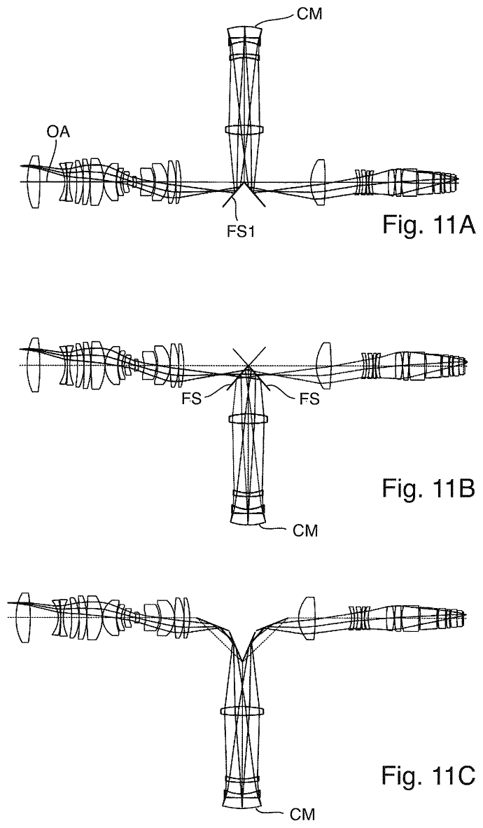

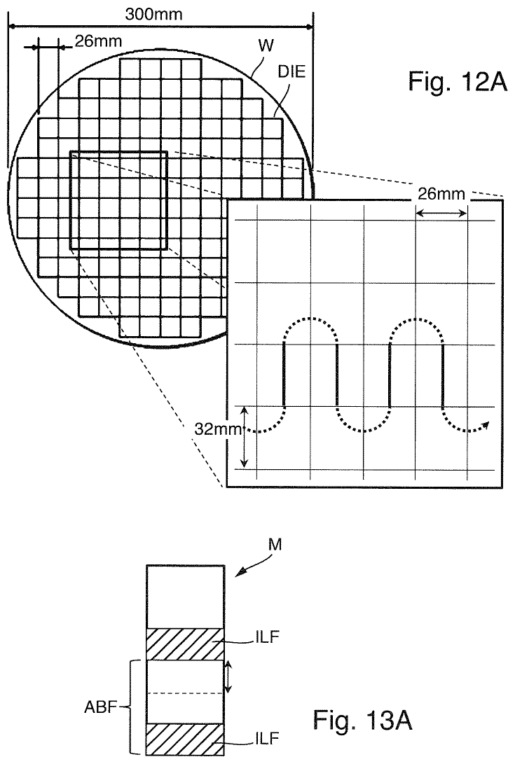

To illustrate the advantages that such double-reflecting deflection units offer in comparison to the prior art, FIGS. 11A to 11C show three folding situations for comparison. FIG. 11A shows “classical” folding in a catadioptric projection lens with a single concave mirror CM. The first deflection mirror FS1, which reflects the radiation coming from the object plane OS to the concave mirror CM, lies on the side, of the parts of the optical axis that are perpendicular to the object plane and image plane, which faces away from the concave mirror. The same applies to the second deflection mirror, which deflects the rays coming from the concave mirror into the third lens part.

If two fields were to be used at the same time, the folding mirror of each field would block the respective beam path of the opposite field. It is therefore only possible to image a single field.

In order to allow the (simultaneous) imaging of two fields, the deflection unit should be located on the side of the optical axis facing the associated horizontal arm or concave mirror. FIG. 11B shows an attempt at an implementation with conventional plane mirrors. In the folding variant in FIG. 11B, the folding mirrors FS reflect in each case in the other direction, i.e. the concave mirror is located on the side which is opposite the effective object field. In this case, the folding mirrors are disposed in their own beam path. As a result, there is no functioning system.

A difference between FIGS. 11B and 11C lies in the fact that the rays in FIG. 11C are located at the first deflection unit on the left (on the object side) of the optical axis of the horizontal arm (OA2) and after the reflection at the concave mirror at the second deflection unit on the right (on the image side) of OA2. In FIG. 11B, this is the other way around. As a result, the second deflection unit would have to be to the left of the first deflection mirror (i.e. closer to the object plane) and thus in the beam path object-first deflection mirror.

FIG. 11C shows for comparison the folding with two deflection mirrors per 90° deflection, i.e. with a two-stage reflective deflection unit according to an exemplary embodiment of the present disclosure. It can be seen that a separation of the beam paths leading to the individual concave mirrors can be achieved in this way.

The following text will explain some practical advantages of dual-field projection lenses. An increase in throughput (exposed components per unit time) can be achieved by the possibility of exposing two off-axis fields simultaneously. This is achieved in the projection lens, among other things, by the fact that two catadioptric partial lenses are contained in the second lens part, that is, two horizontal arms, each containing a concave mirror. The lens parts containing the concave mirrors are symmetric to the symmetry plane. The axis of symmetry is an imaginary line that runs through the optical axis OA and runs parallel to the wide sides of the effective image field.

The field distance ABBF of the two effective image fields in the scan direction (y-direction) is ideally such that the sum of the slit width of one field (A*) and the distance between the two fields corresponds exactly to the width of a stepper field (cf. situation in FIG. 2, which shows the object field).

The dual fields can be used either scanning for a double exposure or with the aid of a step-and-scan method.

In the first case, two identical structures would have to be arranged next to each other on the reticle or mask. During scanning, the substrate, such as a wafer, is exposed in quick succession by the first field with the first structure and then by the second field with the second, identical structure. During a normal scan, regions at the far periphery of the wafer are exposed only once. This can be prevented if the scan is started with some overflow. It is conceivable that the second image field is blocked in the overflow region.

In the second case, two different structures can also be arranged next to each other on the reticle, which can be combined to form a structure that is twice as large. The step-and-scan operation would then scan the two fields and then jump to the next dual field in a stepping step.

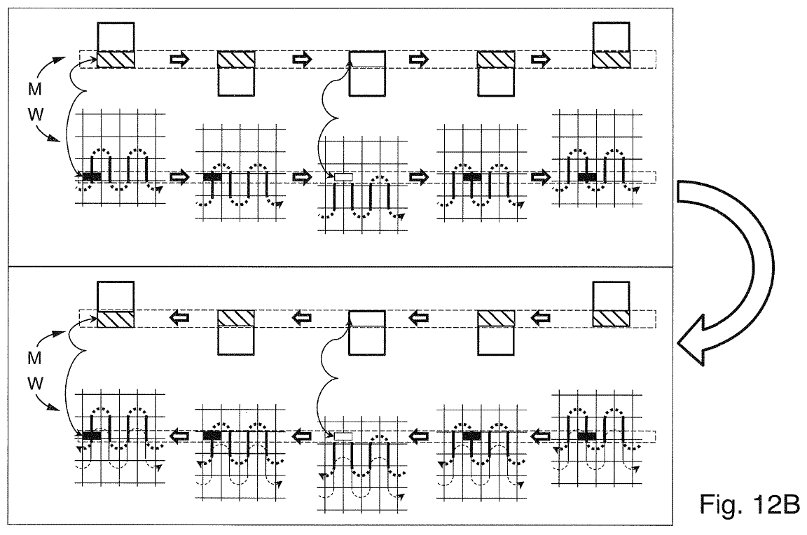

The following figures are used to explain some of the special features of the scanning. FIG. 12A shows a schematic top view of a wafer on which numerous directly adjoining rectangular exposure units DIE (dies) with the current standard dimensions of 26 mm in width and 32 mm in length are provided. The enlarged section in FIG. 12A and FIG. 12B illustrates a typical conventional scanning operation. The wafer meanders under the projection lens or the image field or scanning slit used for the exposure. There are two different states. In a scan phase, which is shown in FIGS. 12A, 12B as a solid line, the substrate and the mask or the wafer and the reticle move at a uniform and adapted speed (depending on the imaging scale of the projection lens) and a die is exposed. After each scanning operation, a change of direction occurs, which is marked in FIGS. 12A, 12B by dashed lines. This stops the movement of the reticle while the wafer is moving. The movement comprises a deceleration phase, a movement perpendicular to the scan direction, and then an acceleration in the opposite direction. There is no exposure during the change of direction, so this phase is not productive. FIGS. 12A, 12B schematically illustrate the chronological sequence of the two phases.

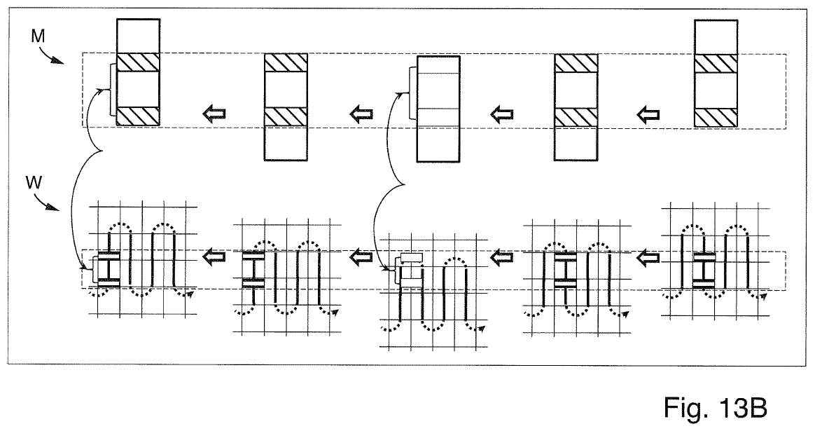

For comparison, FIG. 13B shows different phases of a scanning operation with the aid of a projection exposure apparatus with dual field and two rigidly coupled scanning slits with a geometry, which is shown schematically in FIG. 13A. It is immediately apparent that the scan phases now extend over the length of two immediately successive dies, so that two dies can be exposed simultaneously during a scan phase. In comparison with the scan phases, the unproductive change of direction takes place only half as often as in the classical scanning operation in the sense that, in the classical operation, a change of direction takes place after the scanning of a die, while in the case of a dual field, a change of direction takes place only after the scanning of two dies.

In order to enable this type of scanning, the two scanning slits or the effective image fields in the exemplary embodiment are arranged according to FIG. 13A.

The scanning operation with the double exposure corresponds to the scanning operation for a single field in terms of reticle and wafer movement. One die is exposed in each case for the first time, and an adjacent die is exposed for the second time. The difference to the scanning operation for a single field is that at the top and bottom periphery of the wafer, the illumination of one of the two fields are switched off so that it is not exposed beyond the periphery of the wafer.

The previous examples illustrate that the two-stage folding at the two deflection units of each projection beam path allows the use of dual fields. There are other potential uses and advantages over single folding. One example is the avoidance of the so-called “image flip” with a catadioptric projection lens with a single concave mirror and two intermediate images.

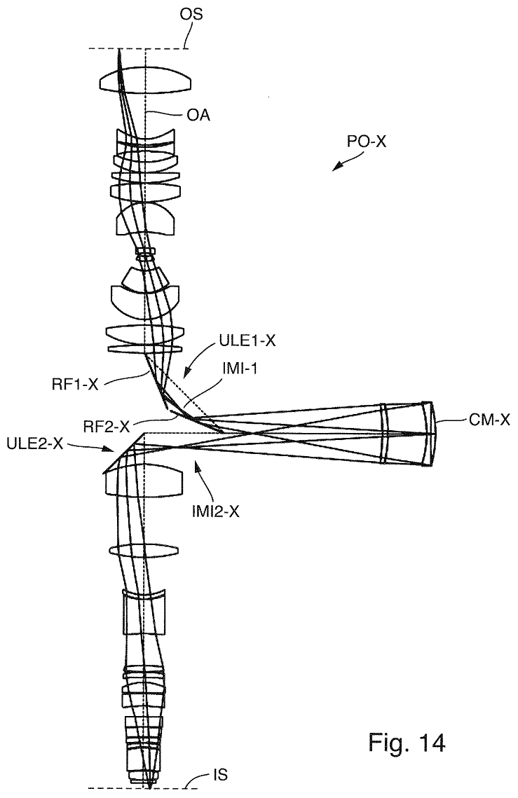

Such projection lenses offer advantages, for example in terms of correcting chromatic aberrations, but have the disadvantage that an “image flip” is generated during the imaging. This means that features which are described in a right-handed coordinate system on the reticle are described with a left-handed coordinate system in the image plane. This unfavorable property results from the fact that the handedness changes between the object plane and the image plane at each intermediate image and at each reflection. If the sum of the number of intermediate images and the number of reflections is an odd number, the result is an image flip. If this sum is an even number, an image flip is avoided. This will be explained below using a comparison between a classical projection lens according to FIG. 11A and a projection lens PO-X according to FIG. 14.

FIG. 14 shows a lens element section through a catadioptric projection lens PO-X, which images an effective object field in the object plane which is located outside the optical axis into an off-axis effective image field in an image plane. Two real intermediate images IMI1-X and IMI2-X are produced between the object plane and the image plane. The projection lens has a single concave mirror with an upstream negative group to support the correction of the chromatic aberrations. A first deflection unit ULE1-X directs the radiation coming from the object plane in the direction of the concave mirror. A second deflection unit ULE2-X directs the radiation reflected by the concave mirror in the direction of the image plane. While the second deflection unit is formed by a simple plane mirror and causes a single reflection, the first deflection unit ULE-X is designed as a two-stage reflective deflection unit. The latter has a first reflection surface RF1-X, which deflects the radiation coming from the object in the direction of a second, immediately following reflection surface RF2-X. The latter then reflects the radiation in the direction of the concave mirror. The two reflection surfaces can then be arranged on separate individual mirrors; they can be formed on a common carrier element in order to fix their mutual orientations. Between the object plane and the image plane there are two intermediate images and a total of four reflections, so the sum of intermediate images and reflections is an even number. Thus, the image flip existing in conventional systems of this type (see FIG. 11A) is avoided. Alternatively, the first deflection unit could be single-stage and the second deflection unit could be two-stage. As with the classical system, the deflection mirrors are each arranged in the optical vicinity of the associated intermediate images, i.e. in a near-field region.

The use of two-stage reflective deflection units of the kind described in this application is not limited to the exemplary embodiments. It is also possible to use such deflection units in a projection lens which produces only one intermediate image between the object plane and the image plane or generates direct imaging without an intermediate image. It may be the case that a two-stage reflective deflection unit is arranged in the projection beam path behind an upstream plane mirror and/or in front of a downstream deflection mirror.

The following tables summarize the specifications of the two exemplary embodiments. Tables 1 and 1A apply to the exemplary embodiment of FIG. 9 with NA=0.3, tables 2 and 2A apply to an exemplary embodiment that is not shown in an image with NA=0.28 and without a positive lens element in the double-passage beam path between the deflection units and the concave mirror.

The tables summarize the specification of the respective design in tabular form. The “SURF” column indicates the number of a refractive surface or surface with a different characteristic, the “RADIUS” column indicates the radius r of the surface (in mm), the “THICKNESS” column indicates the distance d of the surface from the following surface (in mm), and the “MATERIAL” column indicates the material of the optical components. Columns “INDEX1,” INDEX2” and “INDEX3” indicate the refractive index of the material at wavelengths 365.5 nm (INDEX1), 364.5 nm (INDEX2) and 366.5 nm (INDEX3). The “SEMIDIAM” column shows the usable free radii or the half free optical diameters of the lens elements (in mm) or optical elements. The radius r=0 (in the column “RADIUS”) corresponds to a planar surface. Some optical surfaces are aspheric. Tables with the suffix “A” indicate the corresponding asphere data, wherein the aspheric surfaces are calculated according to the following rule:

$$p ( h ) = \frac{ϱ {h}^{2}}{1 + \sqrt{1 - ( 1 + K ) {( ϱ h )}^{2}}} + {C}_{1} {h}^{4} + {C}_{2} {h}^{6} + {C}_{3} {h}^{8} + …$$

The reciprocal value

$$\frac{1}{r} = ϱ$$

of the radius indicates the surface curvature, and h indicates the distance of a surface point from the optical axis (i.e. the ray height). Thus, p(h) indicates the sag height, i.e. the distance of the surface point from the surface vertex in the z-direction (direction of the optical axis). The coefficients K, C1, C2, . . . are shown in the tables with the suffix “A.”

TABLE 1

| SURF | RADIUS | THICKNESS | MATERIAL | INDEX1 | INDEX2 | INDEX3 | SEMID. | TILT | TILT |
|---|---|---|---|---|---|---|---|---|---|
| 0 | planar | [symbol] | | 1 | 1 | 1 | 0.0 | | |
| (OBJ) | | | | | | | | | |
| 1 | 313.659095 | 60.694812 | SIO2 | 1.474188175 | 1.47447703 | 1.4747711 | 110.0 | | |
| 2 | −801.556319 | [symbol] | | 1 | 1 | 1 | 105.8 | | |
| 3 | [symbol] | 10.262231 | SIO2 | 1.474188175 | 1.47447703 | 1.4747711 | 76.1 | | |
| 4 | −396.017812 | 1.463990 | | 1 | 1 | 1 | 78.4 | | |
| 5 | [symbol] | 10.121204 | SIO2 | 1.474188175 | 1.47447703 | 1.4747711 | 78.5 | | |
| 6 | [symbol] | 35.518156 | | 1 | 1 | 1 | 80.3 | | |
| 7 | −462.835188 | 30.596703 | SIO2 | 1.474188175 | 1.47447703 | 1.4747711 | 84.0 | | |
| 8 | −194.369860 | 1.149336 | | 1 | 1 | 1 | 88.9 | | |
| 9 | −1162.886136 | [symbol] | SIO2 | 1.474188175 | 1.47447703 | 1.4747711 | 92.6 | | |
| 10 | −278.287998 | [symbol] | | 1 | 1 | 1 | 95.5 | | |
| 11 | 1420.872642 | 64.194980 | SIO2 | 1.474188175 | 1.47447703 | 1.4747711 | 95.8 | | |
| 12 | −194.503027 | [symbol] | | 1 | 1 | 1 | 97.5 | | |
| 13 | 94.060920 | [symbol] | SIO2 | 1.474188175 | 1.47447703 | 1.4747711 | 78.3 | | |
| 14 | 192.679744 | 1.559950 | | 1 | 1 | 1 | 62.0 | | |
| 15 | [symbol] | 20.032900 | SIO2 | 1.474188175 | 1.47447703 | 1.4747711 | 58.4 | | |
| 16 | [symbol] | 11.814077 | | 1 | 1 | 1 | 46.5 | | |
| 17 | 125.870327 | 22.130617 | SIO2 | 1.474188175 | 1.47447703 | 1.4747711 | 42.1 | | |
| 18 | 61.964170 | 27.496928 | | 1 | 1 | 1 | 29.6 | | |
| 19 | −64.969877 | 15.098409 | SIO2 | 1.474188175 | 1.47447703 | 1.4747711 | 20.5 | | |
| 20 | −100.479377 | 26.837998 | | 1 | 1 | 1 | 23.9 | | |
| 21 | −95.104123 | 57.961946 | SIO2 | 1.474188175 | 1.47447703 | 1.4747711 | 35.1 | | |
| 22 | −117.375749 | [symbol] | | 1 | 1 | 1 | 58.1 | | |
| 23 | [symbol] | 57.688418 | SIO2 | 1.474188175 | 1.47447703 | 1.4747711 | 61.3 | | |
| 24 | −109.341889 | 1.171987 | | 1 | 1 | 1 | 78.8 | | |
| 25 | 751.633206 | 39.157305 | SIO2 | 1.474188175 | 1.47447703 | 1.4747711 | 87.8 | | |
| 26 | [symbol] | 2.358230 | | 1 | 1 | 1 | 89.4 | | |
| 27 | 12076.748826 | 22.217332 | SIO2 | 1.474188175 | 1.47447703 | 1.4747711 | 88.2 | | |
| 28 | −314.824440 | [symbol] | | 1 | 1 | 1 | 88.1 | | |
| 29 | planar | [symbol] | mirror | 1 | 1 | 1 | 146.4 | −67.5 | 67.5 |
| 30 | planar | 198.815860 | mirror | 1 | 1 | 1 | 143.6 | −22.5 | 22.5 |
| 31 | 419.811910 | [symbol] | SIO2 | 1.474188175 | 1.47447703 | 1.4747711 | 90.8 | | |
| 32 | −671.770102 | 283.160703 | | 1 | 1 | 1 | 90.6 | | |
| 33 | [symbol] | 15.517185 | SIO2 | 1.474188175 | 1.47447703 | 1.4747711 | 70.8 | | |
| 34 | −366.537484 | [symbol] | | 1 | 1 | 1 | 72.1 | | |
| 35 | −165.724966 | 16.376894 | SIO2 | 1.474188175 | 1.47447703 | 1.4747711 | 72.1 | | |
| 36 | −2614.277511 | [symbol] | | 1 | 1 | 1 | 77.0 | | |
| 37 | −296.119320 | 47.574101 | mirror | 1 | 1 | 1 | 84.7 | | |
| 38 | 2614.277511 | 16.376894 | SIO2 | 1.474188175 | 1.47447703 | 1.4747711 | 74.0 | | |
| 39 | [symbol] | [symbol] | | 1 | 1 | 1 | 69.5 | | |
| 40 | 366.537484 | 15.517185 | SIO2 | 1.474188175 | 1.47447703 | 1.4747711 | 59.5 | | |
| 41 | 219.406879 | 283.160703 | | 1 | 1 | 1 | 68.2 | | |
| 42 | 671.770102 | 39.209117 | SIO2 | 1.474188175 | 1.47447703 | 1.4747711 | 88.8 | | |
| 43 | −419.811910 | 198.815360 | | 1 | 1 | 1 | 89.0 | | |
| 44 | planar | 275.202116 | mirror | 1 | 1 | 1 | 142.6 | 22.5 | −22.5 |
| 45 | planar | 45.307528 | mirror | 1 | 1 | 1 | 145.2 | 67.5 | −67.5 |
| 46 | 137.863448 | 69.500589 | SIO2 | 1.474188175 | 1.47447703 | 1.4747711 | 94.3 | | |
| 47 | −926.388792 | 156.815279 | | 1 | 1 | 1 | 90.1 | | |
| 48 | −130.164386 | 11.807231 | SIO2 | 1.474188175 | 1.47447703 | 1.4747711 | 52.1 | | |
| 49 | −246.384840 | 14.058199 | | 1 | 1 | 1 | 52.1 | | |
| 50 | −191.014898 | 16.136166 | SIO2 | 1.474188175 | 1.47447703 | 1.4747711 | 50.9 | | |
| 51 | −307.839194 | 1.951201 | | 1 | 1 | 1 | 51.4 | | |
| 52 | 684.683576 | 10.178590 | SIO2 | 1.474188175 | 1.47447703 | 1.4747711 | 51.0 | | |
| 53 | 247.582201 | [symbol] | | 1 | 1 | 1 | 50.3 | | |
| 54 | 146.261249 | 15.541772 | SIO2 | 1.474188175 | 1.47447703 | 1.4747711 | 50.4 | | |
| 55 | 160.475891 | 73.186277 | | 1 | 1 | 1 | 49.0 | | |
| S6 | planar | 5.154755 | | 1 | 1 | 1 | 49.4 | | |
| (STOP) | | | | | | | | | |
| 57 | 413.071260 | [symbol] | SIO2 | 1.474188175 | 1.47447703 | 1.4747711 | 51.9 | | |
| 58 | [symbol] | [symbol] | | 1 | 1 | 1 | 55.3 | | |
| 59 | 343.765147 | [symbol] | SIO2 | 1.474188175 | 1.47447703 | 1.4747711 | 56.9 | | |
| 60 | −863.571059 | 2.179246 | | 1 | 1 | 1 | 57.2 | | |
| 61 | 203.377100 | 73.290044 | SIO2 | 1.474188175 | 1.47447703 | 1.4747711 | 57.0 | | |
| 62 | 2660.834310 | 7.191681 | | 1 | 1 | 1 | 50.4 | | |
| 63 | −559.997454 | 70.864313 | SIO2 | 1.474188175 | 1.47447703 | 1.4747711 | 49.8 | | |
| 64 | 1168.970436 | [symbol] | | 1 | 1 | 1 | 45.2 | | |
| 65 | [symbol] | 30.155097 | SIO2 | 1.474188175 | 1.47447703 | 1.4747711 | 44.9 | | |
| 66 | 8466.525734 | 4.393047 | | 1 | 1 | 1 | 42.9 | | |
| 67 | 234.459718 | 13.609307 | SIO2 | 1.474188175 | 1.47447703 | 1.4747711 | 42.0 | | |
| 68 | 347.975968 | 3.573041 | | 1 | 1 | 1 | 40.5 | | |
| 69 | 173.342050 | 26.558614 | SIO2 | 1.474188175 | 1.47447703 | 1.4747711 | 39.7 | | |
| 70 | 514.184870 | 1.164063 | | 1 | 1 | 1 | 35.9 | | |
| 71 | 191.459647 | [symbol] | SIO2 | 1.474188175 | 1.47447703 | 1.4747711 | 35.3 | | |
| 72 | 889.725826 | [symbol] | | 1 | 1 | 1 | 31.4 | | |
| 73 | planar | 5.570294 | SIO2 | 1.474188175 | 1.47447703 | 1.4747711 | 31.1 | | |
| 74 | planar | 12.080020 | | 1 | 1 | 1 | 30.1 | | |
| 75 | planar | 0.000000 | | 1 | 1 | 1 | 0.0 | | |
| (IMG) | | | | | | | | | |

[symbol]

indicates data missing or illegible when filed

TABLE 1A
ASPHERIC CONSTANTS

| SURF | 1 | 3 | 6 | 27 |
|---|---|---|---|---|
| K | 0 | 0 | 0 | 0 |
| C1 | 7.258868E−08 | 2.011577E−07 | 2.636351E−07 | −2.574222E−08 |
| C2 | −5.430882E−12 | −2.059146E−11 | −3.252204E−11 | −1.424412E−12 |
| C3 | 3.619145E−16 | 1.822025E−15 | 2.293197E−15 | 1.304966E−16 |
| C4 | −1.578232E−20 | −7.313131E−21 | −1.255006E−19 | −2.145075E−20 |
| C5 | 5.134497E−25 | −1.162491E−23 | 5.661107E−24 | 2.041821E−24 |
| C6 | −7.407896E−30 | 1.040102E−27 | −1.798991E−28 | −8.339538E−29 |
| C7 | 0 | 0 | 0 | 0 |
| C8 | 0 | 0 | 0 | 0 |

| SURF | 31 | 36 | 38 | 43 |
|---|---|---|---|---|
| K | 0 | 0 | 0 | 0 |
| C1 | 1.355011E−09 | −4.728914E−09 | 4.728914E−09 | −1.355011E−09 |
| C2 | 5.941808E−13 | −1.372861E−13 | 1.372861E−13 | −5.941808E−13 |
| C3 | −3.597974E−17 | 1.769076E−17 | −1.769076E−17 | 3.597974E−17 |
| C4 | 1.900153E−21 | 3.267795E−21 | −3.267795E−21 | −1.900153E−21 |
| C5 | −2.847826E−25 | −6.532412E−25 | 6.532412E−25 | 2.847826E−25 |
| C6 | 2.050550E−29 | 2.863773E−29 | −2.863773E−29 | −2.050550E−29 |
| C7 | 0 | 0 | 0 | 0 |
| C8 | 0 | 0 | 0 | 0 |

| SURF | 46 | 48 | 57 | 60 | 64 |
|---|---|---|---|---|---|
| K | 0 | 0 | 0 | 0 | 0 |
| C1 | −3.140756E−08 | −7.730092E−08 | −2.290987E−09 | 2.294900E−09 | 5.997172E−08 |
| C2 | −1.203411E−12 | −7.180831E−12 | −5.404557E−12 | −3.127903E−12 | 2.871090E−11 |
| C3 | 3.765773E−17 | 3.021547E−15 | −1.072780E−15 | −9.887066E−16 | −3.926675E−16 |
| C4 | −1.131056E−20 | −1.703028E−18 | 8.128417E−19 | 2.805846E−19 | 3.477523E−19 |
| C5 | 1.036560E−24 | 5.257098E−22 | −1.975107E−22 | −4.541180E−23 | −5.147175E−22 |
| C6 | −5.506043E−29 | −6.121958E−26 | 1.543922E−26 | 2.704394E−27 | 1.933726E−25 |
| C7 | 0 | 0 | 0 | 0 | 0 |
| C8 | 0 | 0 | 0 | 0 | 0 |

TABLE 3

| | | | | | | | | HOA % \| |
|---|---|---|---|---|---|---|---|---|
| SURF | RADIUS | THICKNESS | MATERIAL | INDEX1 | INDEX2 | INDEX3 | SEMID. | TILT |
| 0 | planar | 43.890445 | | 1 | 1 | 1 | 0.0 | |
| (OBJ) | | | | | | | | |
| 1 | 317.336786 | 54.705247 | SILUV | 1.474188175 | 1.47447703 | 1.4747711 | 112.0 | |
| 2 | −561.198473 | 111.946272 | | 1 | 1 | 1 | 107.7 | |
| 3 | −84.127688 | [symbol] | SILUV | 1.474188175 | 1.47447703 | 1.4747711 | 70.1 | |
| 4 | −325.043319 | 6.013108 | | 1 | 1 | 1 | 70.0 | |
| 5 | −204.768360 | 10.666035 | SILUV | 1.474188175 | 1.47447703 | 1.4747711 | 68.9 | |
| 6 | [symbol] | 26.118127 | | 1 | 1 | 1 | 71.2 | |
| 7 | [symbol] | 26.320606 | SILUV | 1.474188175 | 1.47447703 | 1.4747711 | 71.9 | |
| 8 | −147.473400 | [symbol] | | 1 | 1 | 1 | 78.1 | |
| 9 | −3910.921139 | 24.413188 | SILUV | 1.474188175 | 1.47447703 | 1.4747711 | 82.5 | |
| 10 | −251.313470 | 1.033922 | | 1 | 1 | 1 | 83.9 | |
| 11 | 507.858397 | 46.019262 | SILUV | 1.474188175 | 1.47447703 | 1.4747711 | 84.7 | |
| 12 | −251.876631 | 1.111422 | | 1 | 1 | 1 | 84.0 | |
| 13 | 83.552130 | 73.586537 | SILUV | 1.474188175 | 1.47447703 | 1.4747711 | 71.4 | |
| 14 | 196.054018 | 38.923443 | | 1 | 1 | 1 | 49.0 | |
| 15 | 193.743320 | [symbol] | SILUV | 1.474188175 | 1.47447703 | 1.4747711 | [symbol] | |
| 16 | 52.041515 | [symbol] | | 1 | 1 | 1 | [symbol] | |
| 17 | −55.929273 | 11.794515 | SILUV | 1.474188175 | 1.47447703 | 1.4747711 | 17.2 | |
| 18 | −66.852705 | [symbol] | | 1 | 1 | 1 | 22.7 | |
| 19 | −62.710866 | [symbol] | SILUV | 1.474188175 | 1.47447703 | 1.4747711 | 34.1 | |
| 20 | −83.137995 | [symbol] | | 1 | 1 | 1 | 58.3 | |
| 21 | −112.335147 | [symbol] | SILUV | 1.474188175 | 1.47447703 | 1.4747711 | [symbol] | |
| 22 | [symbol] | 14.114156 | | 1 | 1 | 1 | 82.0 | |
| 23 | 585.175867 | 47.785588 | SILUV | 1.474188175 | 1.47447703 | 1.4747711 | 95.4 | |
| 24 | −194.175480 | 1.116844 | | 1 | 1 | 1 | 96.5 | |
| 25 | 517.329281 | [symbol] | SILUV | 1.474188175 | 1.47447703 | 1.4747711 | [symbol] | |
| 26 | −919.103095 | 1.011538 | | 1 | 1 | 1 | 90.4 | |
| 27 | planar | 276.741691 | mirror | 1 | 1 | 1 | 147.4 | −67.5 |
| 28 | planar | 390.934377 | mirror | 1 | 1 | 1 | 142.0 | −67.5 |
| 29 | [symbol] | [symbol] | SILUV | 1.474188175 | 1.47447703 | 1.4747711 | 74.6 | |
| 30 | [symbol] | 95.302534 | | 1 | 1 | 1 | 75.4 | |
| 31 | −250.445951 | 10.423331 | SILUV | 1.474188175 | 1.47447703 | 1.4747711 | 75.9 | |
| 32 | [symbol] | 11.678478 | | 1 | 1 | 1 | 78.4 | |
| 33 | [symbol] | 11.678478 | mirror | 1 | 1 | 1 | 78.4 | |
| 34 | −1672.621399 | 10.423331 | SILUV | 1.474188175 | 1.47447703 | 1.4747711 | 78.4 | |
| 35 | [symbol] | 95.302534 | | 1 | 1 | 1 | 75.9 | |
| 36 | [symbol] | [symbol] | SILUV | 1.474188175 | 1.47447703 | 1.4747711 | 75.2 | |
| 37 | 512.591931 | 390.934377 | | 1 | 1 | 1 | 74.4 | |
| 38 | planar | 276.741691 | mirror | 1 | 1 | 1 | 143.3 | 67.5 |
| 39 | planar | −3.093996 | mirror | 1 | 1 | 1 | 148.5 | 67.5 |
| 40 | [symbol] | [symbol] | SILUV | 1.474188175 | 1.47447703 | 1.4747711 | 94.3 | |

[symbol]

indicates data missing or illegible when filed

TABLE 3A
ASPHERIC CONSTANTS

| SURF | 1 | 3 | 6 | 17 |
|---|---|---|---|---|
| K | 0 | 0 | 0 | 0 |
| C1 | 8.343405E−08 | 5.197994E−07 | 4.357373E−07 | −1.240495E−06 |
| C2 | −1.857642E−12 | −3.604842E−11 | −4.317549E−11 | −5.211367E−09 |
| C3 | −2.394648E−18 | 6.475431E−15 | 3.471888E−15 | 4.301288E−11 |
| C4 | 5.875239E−21 | −4.030577E−20 | −1.523606E−19 | −1.954661E−13 |
| C5 | −1.842466E−25 | 1.195428E−23 | −9.260882E−25 | 4.495646E−16 |
| C6 | −7.993131E−30 | 5.758602E−27 | 8.725334E−27 | −9.598243E−19 |
| C7 | −5.447442E−34 | −1.831438E−30 | −2.400936E−30 | 3.084553E−21 |
| C8 | 5.957414E−38 | 2.882257E−34 | 1.949680E−34 | −4.755141E−24 |

| SURF | 19 | 25 | 32 | 34 |
|---|---|---|---|---|
| K | 0 | 0 | 0 | 0 |
| C1 | 2.351387E−07 | −4.070498E−08 | −6.699475E−09 | 6.699475E−09 |
| C2 | 4.179078E−10 | −2.318935E−13 | −2.187419E−13 | 2.187419E−13 |
| C3 | −4.172236E−13 | −3.254201E−16 | 9.752181E−17 | −9.752181E−17 |
| C4 | 4.340189E−16 | 7.980012E−20 | −9.830275E−21 | 9.830275E−21 |
| C5 | −5.605434E−19 | −1.220270E−23 | 3.362668E−25 | −3.362668E−25 |
| C6 | 4.681548E−22 | 8.645204E−28 | −2.715949E−28 | 2.715949E−28 |
| C7 | −1.527855E−25 | −1.393533E−32 | 1.206633E−31 | −2.677731E−33 |
| C8 | 3.779847E−30 | −9.471846E−37 | −1.146114E−35 | −3.939833E−36 |

| SURF | 40 | 44 | 49 | 52 | 60 | 67 |
|---|---|---|---|---|---|---|
| K | 0 | 0 | 0 | 0 | 0 | 0 |
| C1 | −3.065834E−08 | 2.360624E−08 | 2.448140E−07 | 2.367421E−07 | 2.719354E−07 | 3.815887E−07 |
| C2 | 2.654377E−13 | −1.492506E−12 | −3.839945E−11 | −2.349121E−11 | 6.515650E−11 | −2.605052E−10 |
| C3 | −6.061174E−18 | 2.165630E−14 | 3.607894E−14 | 2.226650E−14 | 1.905337E−14 | 5.005764E−13 |
| C4 | 4.757296E−21 | −2.558652E−17 | −1.090641E−17 | −3.064922E−18 | −5.192838E−17 | −9.098221E−16 |
| C5 | −4.681420E−24 | 1.723006E−20 | −2.832473E−21 | −6.695116E−21 | 5.486918E−20 | 8.249081E−19 |
| C6 | 1.087152E−27 | −6.544300E−24 | 2.340678E−24 | 4.670988E−24 | −3.514661E−23 | −2.134755E−22 |
| C7 | −1.057149E−31 | 1.302283E−27 | −3.866787E−28 | −1.258728E−27 | 1.339572E−26 | −1.533643E−25 |
| C8 | 3.773424E−36 | −1.054878E−31 | 1.277414E−33 | 1.255664E−31 | −2.194746E−30 | 7.918414E−29 |

What is claimed is:

1. A dual-field illumination system configured to receive a single light beam from a primary light source and to simultaneously produce first and second illumination beams from the single light beam, the first illumination beam being guidable along a first illumination beam path to a first illumination field outside an optical axis of the projection lens in an exit plane of the illumination system, and the second illumination beam being guidable along a second illumination beam path to a second illumination field outside the optical axis in the exit plane and opposite the first illumination field with respect to the optical axis, the dual-field illumination system comprising:
a refractive pupil-shaping unit configured to receive light from the primary light source and to generate a two-dimensional intensity distribution in a pupil-shaping surface of the dual-field illumination system; and
a refractive field-shaping system optically downstream of the pupil-shaping unit, the refractive field-shaping system comprising a homogenization unit configured to homogenize light received from the refractive pupil-shaping unit and to divide the light into the first and second illumination beams,
wherein the dual-field illumination system is a microlithography dual-field illumination system.

2. The dual-field illumination system of claim 1, wherein the illumination system is free of diffractive optical elements.

3. The dual-field illumination system of claim 1, wherein the homogenization unit comprises:
an entry integrator rod with an entry surface and an exit surface;
a first exit integrator rod optically coupled to a first partial surface of the exit surface; and
a second exit integrator rod optically coupled to a second partial surface of the exit surface,
wherein an exit surface of the first exit integrator rod is assigned to the first illumination field, and an exit surface of the second exit integrator rod is assigned to the second illumination field.

4. The dual-field illumination system of claim 3, wherein the illumination system is free of diffractive optical elements.

5. The dual-field illumination system of claim 3, wherein:
for each of the entry integrator rod and the first and second exit integrator rods, the rod has a constant cross-sectional shape and cross-sectional size in an axial direction; and
the homogenization unit further comprises a prism arrangement disposed a distance from the optical axis and between the exit surface of the entry integrator rod and the entry surfaces of the first and second exit integrator rods;
the prism arrangement is configured to deflect a light beam from a first location to a second location; and
the first location is closer to the optical axis than is the second location.

6. The dual-field illumination system of claim 3, wherein:
the first exit integrator rod has a cross-sectional shape that decreases continuously from its entry side to its exit side; and
the second exit integrator rod has a cross-sectional shape that decreases continuously from its entry side to its exit side.

7. The dual-field illumination system of claim 1, wherein the homogenization unit comprises:
a first grid arrangement comprising first refractive grid elements configured to receive light of the two-dimensional intensity distribution and to generate a grid arrangement of secondary light sources; and
a second grid arrangement comprising second refractive grid elements configured to receive light from the secondary light sources to at least partially superimpose light from the secondary light sources in the exit plane,
wherein:
each first grid element is configured to produces an optical channel;
each second grid element is assigned to two adjacent first grid elements;
each second grid element comprises a lens element comprising a first portion located in a first optical channel and a second portion in a second optical channel, the first portion having a different surface shape than a surface shape of the second portion.

8. The dual-field illumination system of claim 7, wherein the illumination system is free of diffractive optical elements.

9. The dual-field illumination system of claim 8, wherein first grid elements which are adjacent in one direction are alternately assigned to the first illumination field and the second illumination field.

10. The dual-field illumination system of claim 8, wherein at least one surface of the lens element of the second grid arrangement is aspherically curved.

11. The dual-field illumination system of claim 8, wherein an entry surface of the lens element of the second grid arrangement is aspherically curved, and an exit surface of the lens of the second grid arrange is aspherically curved.

12. The dual-field illumination system of claim 8, wherein, for at least one lens element of the second grid arrangement, the lens element comprises a buckling line extending between the first portion and the second portion.

13. An apparatus, comprising:
the dual-field illumination system of claim 1; and
a projection lens configured to simultaneously image: i) the first illumination field along a first projection beam path into a first effective image field located outside the optical axis in an image plane; and ii) the second illumination field along a second projection beam path into a second effective image field located outside the optical axis in the image plane,
wherein the apparatus is a microlithography projection exposure apparatus.

14. The apparatus of claim 13, wherein the illumination system is free of diffractive optical elements.

15. The apparatus of claim 13, wherein:
the first and second illumination fields are in an object plane of the projection lens;
the projection lens is a catadioptric projection lens which comprises a plurality of lens elements and concave mirrors between the object plane and the image plane along an optical axis of the projection lens.

16. The apparatus of claim 15, wherein each of the first and second projection beam paths comprises a first deflection unit configured to deflect the radiation coming from the object plane to a concave mirror and a second deflection unit configured to deflect the radiation coming from the concave mirror in a direction of the image plane.

17. The apparatus of claim 16, wherein the projection lens comprises:
a first lens part configured to image each of the first and second illumination fields into a first real intermediate image;
a second lens part configured to generate a second real intermediate image with the radiation coming from the first lens part; and
a third lens part configured to image the second real intermediate image into the image plane.

18. The apparatus of claim 17, wherein the concave mirror is in a region of a pupil surface between the first and the second intermediate images, the first deflection unit is in an optical vicinity of the first intermediate image, and the second deflection unit is arranged in an optical vicinity of the second intermediate image.

19. The apparatus of claim 18, comprising a two-stage reflective deflection unit in a projection beam path, wherein the two-stage reflective deflection unit comprises a first reflection surface and immediately following a second reflection surface, the first reflection surface is configured to deflect the radiation coming from the object plane to the second reflection surface, and the second reflection surface is configured to deflect the radiation coming from the first reflection surface in the direction of the image plane.

20. A method of using a microlithography projection exposure apparatus comprising a dual-field illumination system and a projection lens, the method comprising:
using the dual-field illumination system to illuminate an object in an object plane; and
using the projection lens to project the illuminated object into an image plane,
wherein the dual-field illumination system is a dual-field illumination system according to claim 1, and the first and second illumination fields are in the object plane.
